(19) United States
(12) Patent Application Publication
(10) Pub. No.: US 2013/0032874 A1
(43) Pub. Date: Feb. 7, 2013

(54) METHOD FOR MANUFACTURING NONVOLATILE SEMICONDUCTOR MEMORY DEVICE AND NONVOLATILE SEMICONDUCTOR MEMORY DEVICE

(71) Applicant: Nikka KO, Mie-ken (JP)

(72) Inventor: Nikka KO, Mie-ken (JP)

(73) Assignee: KABUSHIKI KAISHA TOSHIBA, Tokyo (JP)

(21) Appl. No.: 13/351,420

(22) Filed: Jan. 17, 2012

(30) Foreign Application Priority Data
Aug. 5, 2011 (JP) 2011-172199

(51) Int. Cl. H01L 29/792; H01L 21/20

(52) U.S. Cl. 257/324; 438/478; 257/E29.309; 257/E29.262; 257/E21.09

(57) ABSTRACT

According to one embodiment, a method is disclosed for manufacturing a nonvolatile semiconductor memory device. The device includes a plurality of electrode films stacked along a first axis perpendicular to a major surface of a substrate, a plurality of semiconductor layers penetrating through the electrode films, and a memory film provided between the electrode films and the semiconductor layer. The method can include forming a first stacked body by alternately stacking a plurality of first films and second films. The method can include forming a support unit supporting the first films. The method can include forming a first hole and removing the second films via the first hole to form a second stacked body. The method can include forming a plurality of through holes penetrating through the first films. In addition, the method can include burying the memory film and the semiconductor layers in the through holes.

### CROSS-REFERENCE TO RELATED APPLICATIONS

This application is based upon and claims the benefit of priority from the prior Japanese Patent Application No. 2011-172199 filed on Aug. 5, 2011; the entire contents of which are incorporated herein by reference.

### FIELD

Embodiments described herein relate generally to a method for manufacturing a nonvolatile semiconductor memory device and a nonvolatile semiconductor memory device.

### BACKGROUND

These days, a three-dimensionally stacked nonvolatile semiconductor memory device is proposed in which multiple conductive films are collectively processed to increase the memory capacity of the memory. The nonvolatile semiconductor memory device includes a stacked body including alternately stacked insulating films and electrode films, a silicon pillar penetrating through the stacked body, and a memory film between the silicon pillar and the electrode films. In the structure, a memory cell is formed at a facing portion of the silicon pillar and each electrode film.

An improvement in productivity is desired for such a three-dimensionally stacked nonvolatile semiconductor memory device.

### BRIEF DESCRIPTION OF THE DRAWINGS

FIG. 1 is a schematic perspective view illustrating the configuration of a nonvolatile semiconductor memory device;

FIG. 2 is a schematic cross-sectional view illustrating the configuration of the nonvolatile semiconductor memory device;

FIG. 3 is a schematic cross-sectional view illustrating the configuration of a part of the nonvolatile semiconductor memory device;

FIG. 4 is a flow chart illustrating a manufacturing method according to an embodiment;

FIGS. 5 to 9 schematic cross-sectional views illustrating the method for manufacturing a nonvolatile semiconductor memory device according to the embodiment;

FIG. 10 is a flow chart illustrating a specific example of the manufacturing method according to the embodiment;

FIG. 11A to FIG. 19B are schematic views illustrating the method for manufacturing a nonvolatile semiconductor memory device according to the specific example;

FIGS. 20A to 20B are schematic cross-sectional views illustrating formation of a memory film;

FIG. 21A to FIG. 22B are schematic views showing other examples of a first hole; and

FIG. 23 is a schematic perspective view illustrating the configuration of another nonvolatile semiconductor memory device.

### DETAILED DESCRIPTION

According to one embodiment, a method is disclosed for manufacturing a nonvolatile semiconductor memory device. The device includes a plurality of electrode films stacked along a first axis perpendicular to a major surface of a substrate, a plurality of semiconductor layers penetrating through the plurality of electrode films along the first axis, and a memory film provided between the plurality of electrode films and the semiconductor layer. The method can include forming a first stacked body by alternately stacking a plurality of first films and a plurality of second films. The plurality of first films form the plurality of electrode films. The method can include forming a support unit lying along the first axis, the unit supporting the plurality of first films. The method can include forming a first hole penetrating through the first stacked body along the first axis and removing the second films via the first hole to form a second stacked body with a space formed between the plurality of first films. The method can include forming a plurality of through holes penetrating through the plurality of first films of the second stacked body along the first axis. In addition, the method can include burying the memory film and the semiconductor layers in the plurality of through holes.

Various embodiments will be described hereinafter with reference to the accompanying drawings.

The drawings are schematic or conceptual; and the relationships between the thickness and width of portions, the proportional coefficients of sizes among portions, etc., are not necessarily the same as the actual values thereof. Further, the dimensions and proportional coefficients may be illustrated differently among drawings, even for identical portions.

In the specification of the application and the drawings, components similar to those described in regard to a drawing thereinabove are marked with the same reference numerals, and a detailed description is omitted as appropriate.

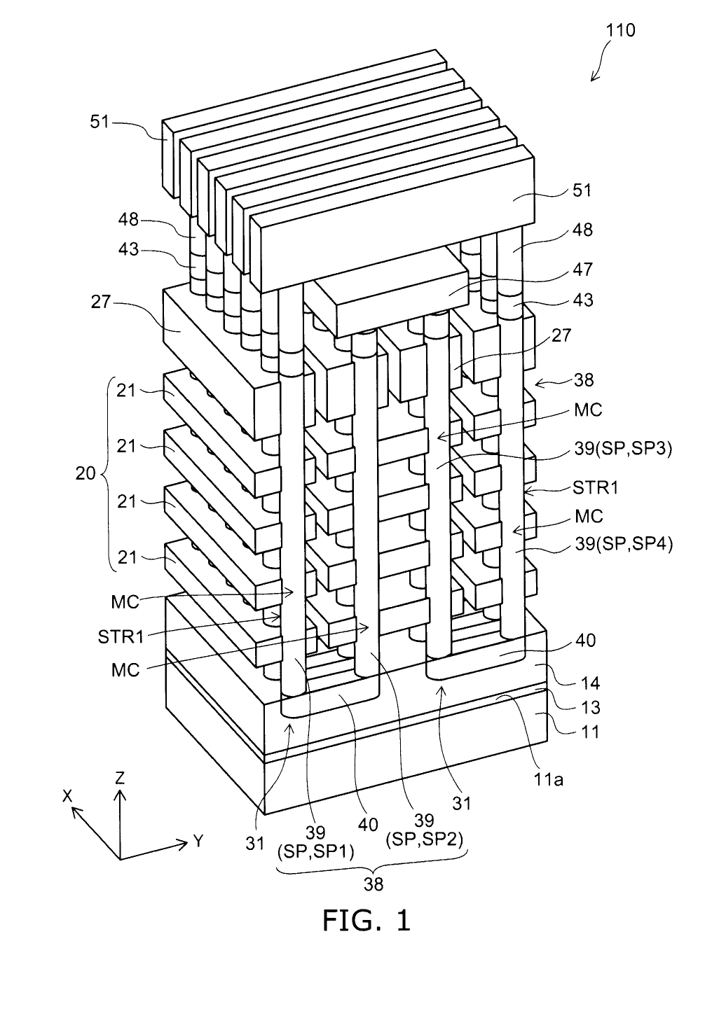

FIG. 1 is a schematic perspective view illustrating the configuration of a nonvolatile semiconductor memory device.

In FIG. 1, for easier viewing of the drawing, only the conductive portions are shown and the insulating portions are omitted.

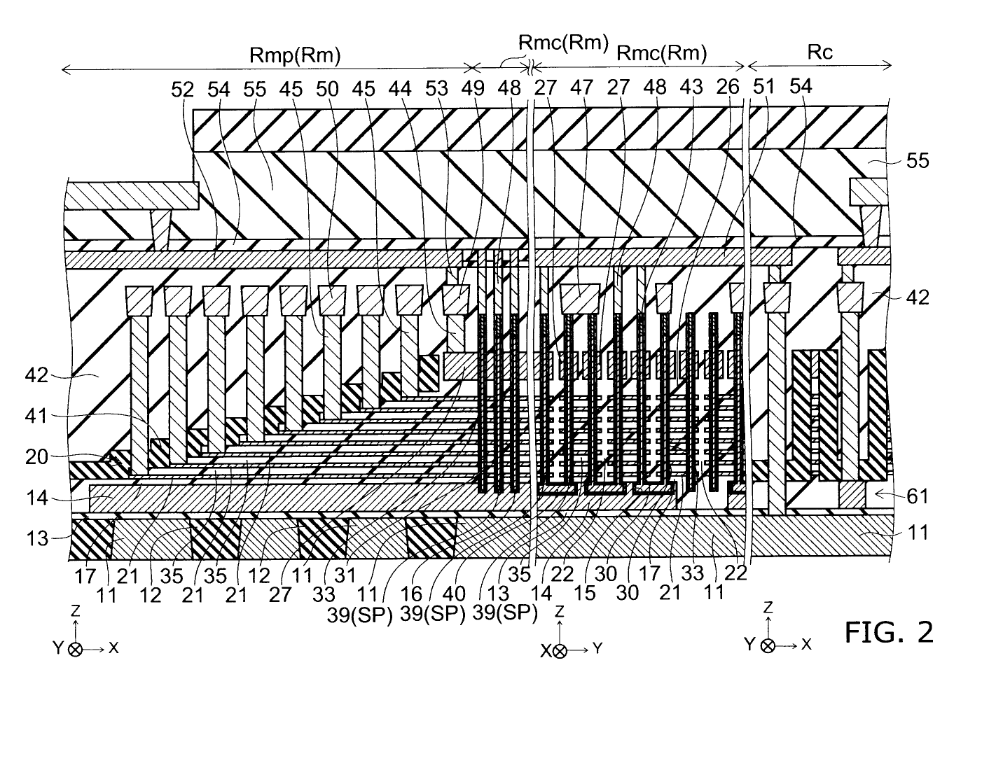

FIG. 2 is a schematic cross-sectional view illustrating the configuration of the nonvolatile semiconductor memory device.

FIG. 2 shows an end portion of a memory array region, a central portion of the memory array region, and a peripheral circuit region.

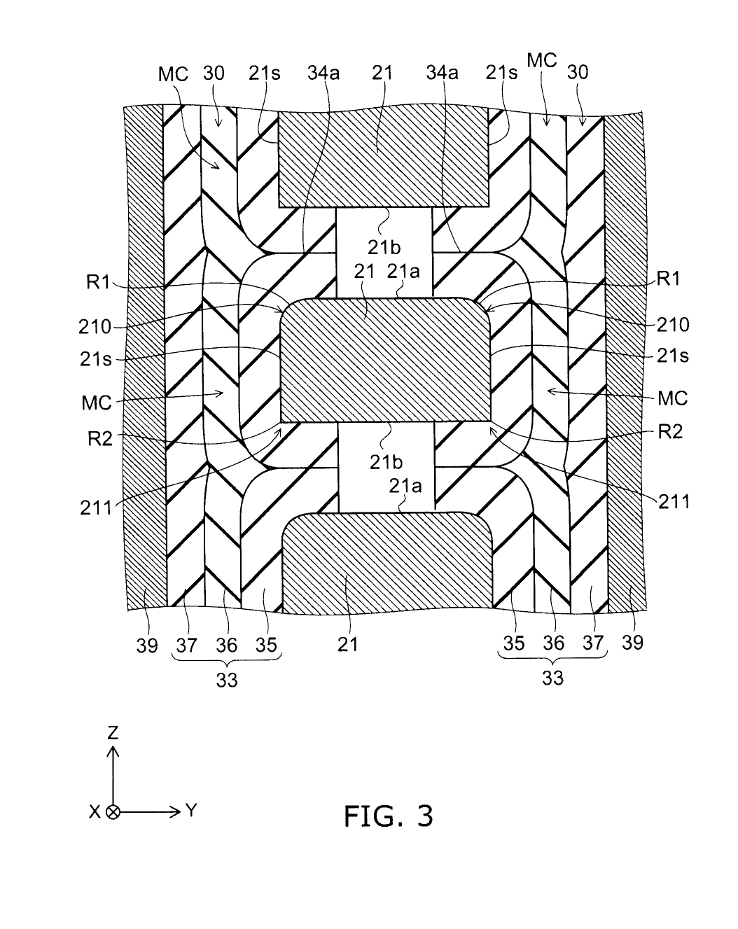

FIG. 3 is a schematic cross-sectional view illustrating the configuration of a part of the nonvolatile semiconductor memory device.

FIG. 3 illustrates a part of electrode films and memory films.

In the embodiment, a method for manufacturing a nonvolatile semiconductor memory device 110 shown in FIG. 1 to FIG. 3 is described as an example.

First, the nonvolatile semiconductor memory device 110 is described.

As shown in FIG. 1 to FIG. 3, the nonvolatile semiconductor memory device 110 includes a plurality of electrode films 21 provided above a substrate 11, semiconductor layers 39, and memory films 33.

In the specification, the axis orthogonal to a major surface 11a of the substrate 11 is defined as the Z-axis (first axis), one of the axes (second axes) orthogonal to the Z-axis is defined as the X-axis, and another (third axis) of the axes (second axes) orthogonal to the Z-axis and orthogonal also to the X-axis is defined as the Y-axis.

A direction moving away from the major surface 11a of the substrate 11 along the Z-axis is referred to as upward (the upper side), and the opposite direction is referred to as downward (the lower side).

The plurality of electrode films 21 are stacked along the Z-axis. In the specific example, as one example, four electrode films 21 are stacked along the Z-axis at prescribed intervals. For convenience of description, an example of including four electrode films 21 is described in the embodiment, but the case where the electrode film 21 is provided other than four in number is similarly described.

The semiconductor layer 39 is opposed to side surfaces 21s of the plurality of electrode films 21. The semiconductor layer 39 is, for example, a semiconductor pillar SP provided in a columnar shape along the Z-axis. The semiconductor pillar SP is, for example, a solid structure made of a semiconductor material. The semiconductor pillar SP may be a hollow structure made of a semiconductor material. The semiconductor pillar SP may include, for example, an insulating layer inside the hollow structure.

The memory film 33 is provided between the side surface 21s of each of the plurality of electrode films 21 and the semiconductor layer 39. A memory cell transistor is formed from the memory film 33 provided at the facing portion of the side surface 21s of the electrode film 21 and the semiconductor film 39. Memory cell transistors are arranged in a three-dimensional matrix configuration, and each memory cell transistor functions as a memory cell MC that stores information (data) by storing a charge in this memory layer (a charge storage film 36).

The semiconductor layer 39 is included in the semiconductor pillar SP extending in the Z-axis. In the nonvolatile semiconductor memory device 110, a U-shaped memory string STR1 is formed from two semiconductor pillars

SP adjacent along the Y-axis and a connection member 40 connecting the ends of the two semiconductor pillars. The plurality of memory strings STR1 are arranged in a matrix configuration on the substrate 11.

Silicon, for example, is used for the substrate 11. In the embodiment, an example of using the substrate 11 of silicon is described as an example.

As shown in FIG. 2, in a memory array region Rm, a silicon oxide film 13 is formed on the substrate 11, and a back gate electrode 14 made of an electrically conductive material, such as silicon doped with phosphorus (phosphorus-doped silicon), is provided thereon.

In a central portion Rmc of the memory array region Rm, a recess 15 extending in the Y-axis direction is formed in a plurality in an upper portion of the back gate electrode 14. A silicon oxide film 16, for example, is provided on the inner surface of the recess 15. A silicon oxide film 17 is provided on the back gate electrode 14.

A stacked body 20 is provided on the silicon oxide film 17. The plurality of electrode films 21 are provided in the stacked body 20. Silicon doped with boron (boron-doped silicon), for example, is used for the electrode film 21. The electrode film 21 functions as the gate electrode of the memory cell transistor. The electrode film 21 is in a band shape extending along the X-axis, and is arranged in a matrix configuration along the Y-axis and the Z-axis.

The plurality of electrode films 21 are fashioned in a stairstep configuration in an end portion Rmp of the memory array region Rm.

An insulating plate member 22 made of, for example, silicon oxide is provided between electrode films 21 adjacent along the Y-axis. The insulating plate member 22 is configured to penetrate through the stacked body 20. A block insulating film 35 (see FIG. 3) described later is embedded between electrode films 21 adjacent along the Z-axis. The block insulating film 35 may be embedded between all the electrode films 21 adjacent along the Z-axis, or may be partially provided to leave a space.

A silicon oxide film 26 is provided on the stacked body 20. A control electrode 27 is provided on the silicon oxide film 26. Boron-doped silicon, for example, is used for the control electrode 27. The control electrode 27 extends along the X-axis. The control electrode 27 is provided for each semiconductor pillar SP.

A plurality of through holes 30 extending along the Z-axis are formed in the stacked body 20, the silicon oxide film 26, and the control electrode 27. The plurality of through holes 30 are arranged in a matrix configuration along the X-axis and the Y-axis. The through holes 30 penetrate through the control electrode 27, the silicon oxide film 26, and the stacked body 20, and reach both ends along the Y-axis of the recess 15. Thereby, a pair of through holes 30 adjacent along the Y-axis are connected by the recess 15 to constitute one U-shaped hole 31. Each through hole 30 is in a circular columnar shape, for example. Each U-shaped hole 31 is almost in a U-shaped configuration.

As shown in FIG. 1 and FIG. 3, a block insulating film 35 is provided on the inner surface of the U-shaped hole 31. The block insulating film 35 is a film that conducts substantially no current even upon application of a voltage in the range of the driving voltage of the nonvolatile semiconductor memory device 110. A high-dielectric material, such as a material with a dielectric constant higher than the dielectric constant of the material of a charge storage film 36 described later (e.g., silicon oxide), is used for the block insulating film 35. The block insulating film 35 goes round from on the inner surface of the through hole 30 to the upper side of a surface 21a (the upper surface) and the lower side of a surface 21b (the lower surface) of the electrode film 21.

A charge storage film 36 is provided on the block insulating film 35. The charge storage film 36 is a film that stores a charge. The charge storage film 36 is, for example, a film including trap sites for electrons. A silicon nitride film, for example, is used as the charge storage film 36.

A tunnel insulating film 37 is provided on the charge storage film 36. The tunnel insulating film 37 is a film that is usually insulative but passes a tunnel current upon application of a prescribed voltage in the range of the driving voltage of the device 110. Silicon oxide, for example, is used for the tunnel insulating film 37. The memory film 33 includes the stacked film of the block insulating film 35, the charge storage film 36, and the tunnel insulating film 37.

The semiconductor layer 39 is embedded in the U-shaped hole 31. Polysilicon containing an impurity (e.g., phosphorus) is used for the semiconductor layer 39. A U-shaped pillar 38 is formed by embedding the semiconductor layer 39 in the U-shaped hole 31. The U-shaped pillar 38 is in a U-shaped configuration reflecting the shape of the U-shaped hole 31.

The U-shaped pillar 38 is in contact with the tunnel insulating film 37. Of the U-shaped pillar 38, the portion located in the through hole 30 is the semiconductor pillar SP, and the portion located in the recess 15 is the connection member 40.

Of the plurality of semiconductor pillars SP, the semiconductor pillars SP in the same column aligned along the X-axis penetrate through the same electrode film 21. Of the four semiconductor pillars SP1 to SP4 included in two U-shaped pillars 38 adjacent along the Y-axis, the inner two semiconductor pillars SP2 and SP3 penetrate through the same electrode film 21. Of the four semiconductor pillars SP1 to SP4 mentioned above, the outer two semiconductor pillars SP1 and SP4 penetrate through the same electrode film 21. A configuration in which each semiconductor pillar SP penetrates through a different electrode film 21 is also possible.

As shown in FIG. 2, in the end portion Rmp of the memory array region Rm, a silicon nitride film 41 is provided on the side surface of the stacked body 20 fashioned in a stairstep configuration, the side surface of the silicon oxide film 26, and the side surface of the control electrode 27. The silicon nitride film 41 is formed in a stairstep configuration to reflect the shape of the end portion of the stacked body 20. An interlayer insulating film 42 made of, for example, silicon oxide is provided on the control electrode 27 and the silicon nitride film 41 to embed the stacked body 20 therein.

A plug 43 and contacts 44 and 45 are embedded in the interlayer insulating film 42. The plug 43 is placed immediately above the semiconductor pillar SP, and is connected to the semiconductor pillar SP. The contact 44 is placed immediately above one end portion along the X-axis of the control electrode 27, and is connected to the contact electrode 27. The contact 45 is placed immediately above one end portion along the X-axis of the electrode film 21, and is connected to the electrode film 21.

A source line 47, a plug 48, and interconnections 49 and 50 are embedded in portions above the plug 43 and the contacts 44 and 45 of the interlayer insulating film 42. The source line 47 extends along the X-axis, and is connected to one of the pair of semiconductor pillars SP included in the

U-shaped pillar 38 via the plug 43. The plug 48 is connected to the other of the pair of semiconductor pillars SP included in the U-shaped pillar 38 via the plug 43. The interconnections 49 and 50 extend along the Y-axis, and are connected to the contacts 44 and 45, respectively.

A bit line 51 extending along the Y-axis is provided on the interlayer insulating film 42, and is connected to the plug 48. An interconnection 52 is provided on the interlayer insulating film 42, and is connected to the interconnection 49 via the plug 53. A silicon nitride film 54 and an interlayer insulating film 55 are provided on the interlayer insulating film 42 so as to embed the bit line 51 and the interconnection 52 therein, and prescribed interconnections etc. are embedded therein.

As shown in FIG. 2, in a peripheral circuit region Rc, a transistor 61 etc. are formed in a region above the substrate 11. The interlayer insulating film 42, the silicon nitride film 54, and the interlayer insulating film 55 are provided above the substrate 11. Prescribed interconnections etc. are embedded in the peripheral circuit region Rc.

Next, a method for manufacturing a nonvolatile semiconductor memory device according to the embodiment is described.

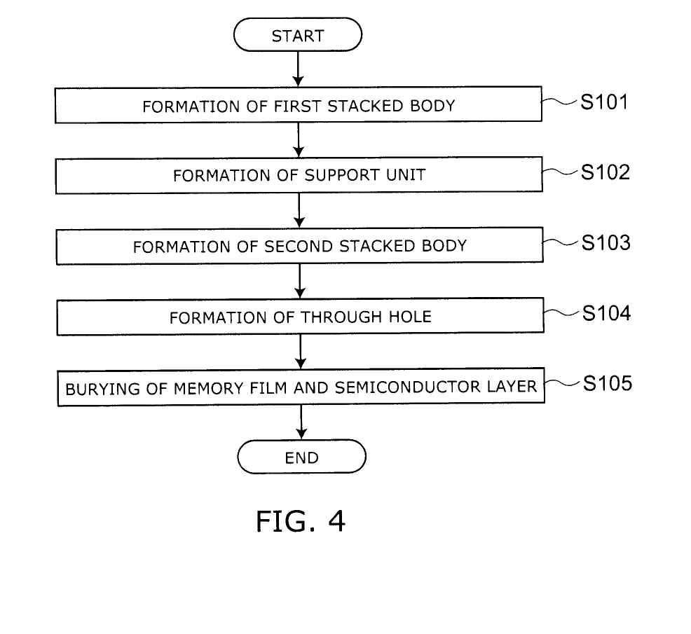

FIG. 4 is a flow chart illustrating a manufacturing method according to the embodiment.

The method for manufacturing a nonvolatile semiconductor memory device according to the embodiment includes the formation of a first stacked body (step S101), the formation of a support unit (step S102), the formation of a second stacked body (step S103), the formation of a through hole (step S104), and the burying of a memory film and a semiconductor layer (step S105).

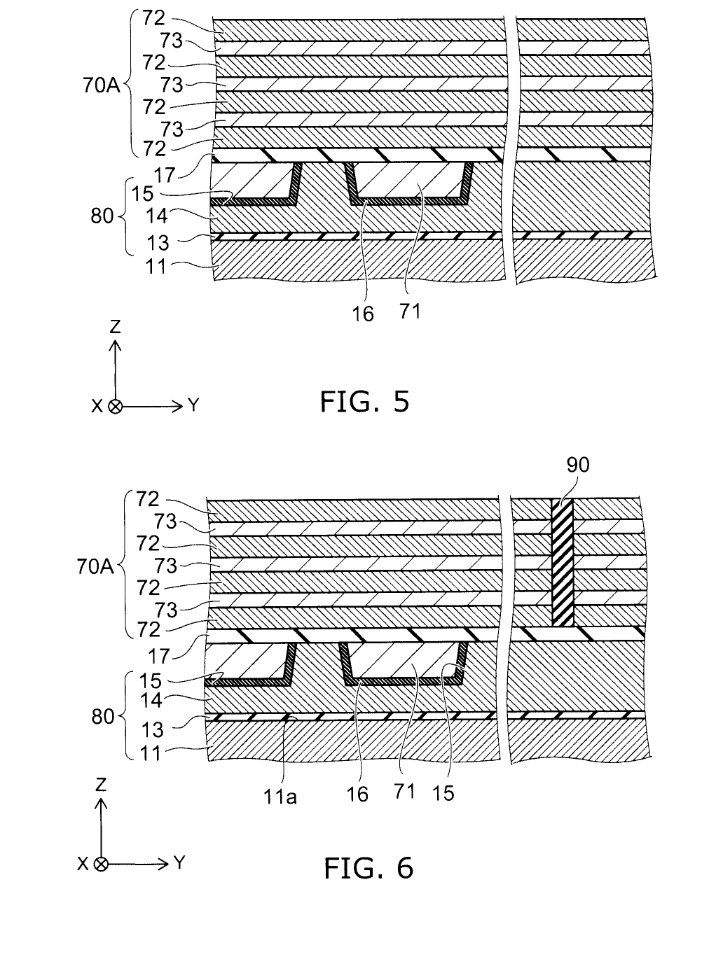

FIG. 5 to FIG. 9 are schematic cross-sectional views illustrating the method for manufacturing a nonvolatile semiconductor memory device according to the embodiment.

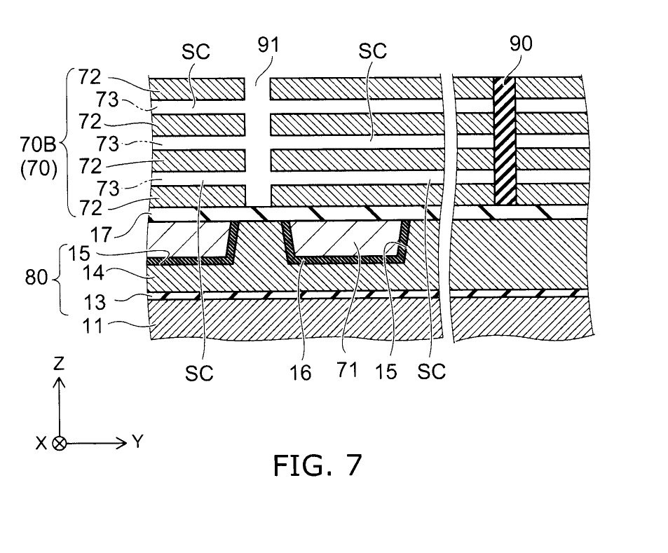

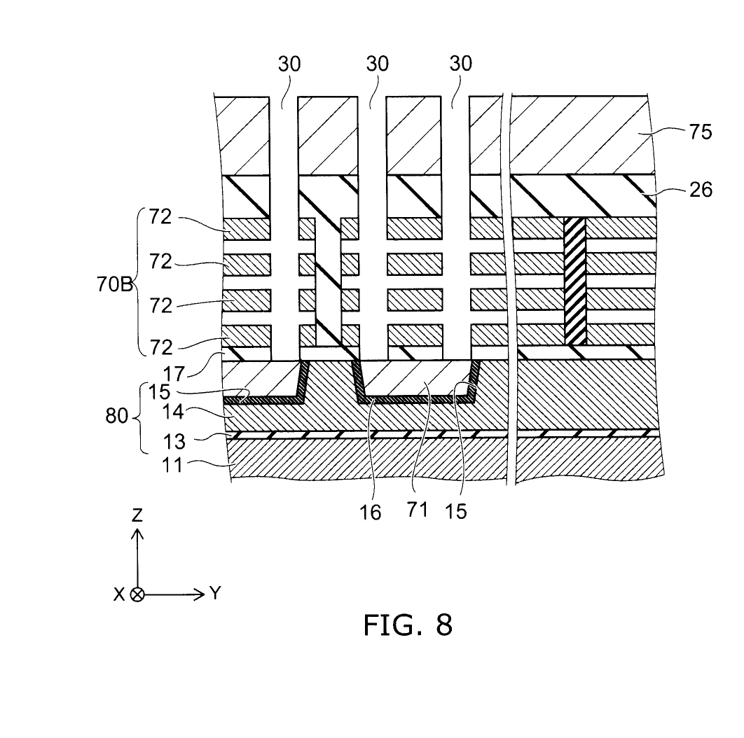

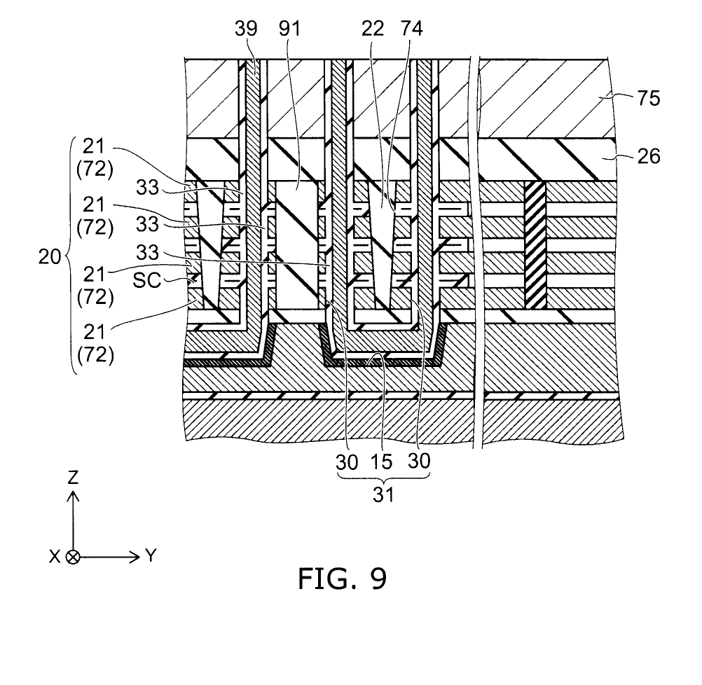

FIG. 5 shows an example of the processing of step S101 shown in FIG. 4. FIG. 6 shows an example of the processing of step S102 shown in FIG. 4. FIG. 7 shows an example of the processing of step S103 shown in FIG. 4. FIG. 8 shows an example of the processing of step S104 shown in FIG. 4. FIG. 9 shows an example of the processing of step 5105 shown in FIG. 4.

First, as shown in FIG. 5 (step S101 of FIG. 4), a first stacked body 70A is formed. The first stacked body 70A is a structure in which a plurality of first films 72 that form the plurality of electrode films 21 and a plurality of second films 73 are alternately stacked. A boron-doped polysilicon film, for example, is used as the first film 72. At least one of, for example, a silicon oxide film (SiO₂), a silicon nitride film (SiN), and a silicon oxycarbide film (SiOC) is used as the second film 73.

The first stacked body 70A is a structure in which the plurality of first films 72 and the plurality of second films 73 are alternately stacked along the Z-axis one by one.

In the embodiment, for example, a structure body 80 is formed on the major surface 11a of the substrate 11. The first stacked body 70A is formed on the structure body 80. The structure body 80 includes, for example, the silicon oxide film 13, the back gate electrode 14, the silicon oxide film 16 and a non-doped silicon unit 71 formed in the recess 15, and the silicon oxide film 17. The silicon oxide film 13 is formed on the major surface 11a of the substrate 11. The back gate electrode 14 is formed on the silicon oxide film 13. The recess 15 is formed in part of the back gate electrode 14. The non-doped silicon unit 71 is formed on the inner surface of the recess 15 via the silicon oxide film 16. The silicon oxide film 17 is formed on the entire surface of the back gate electrode 14.

The first films 72 and the second films 73 are alternately stacked on the silicon oxide film 17 of the structure body 80 to form the first stacked body 70A. In the example shown in FIG. 5, four first films 72 and three second films 73 are alternately stacked one by one.

Next, as shown in FIG. 6 (step S102 of FIG. 4), a support unit 90 is formed. The support unit 90 lies along the Z-axis, and supports the plurality of first films 72. The support unit 90 is provided to penetrate through the first stacked body 70A along the Z-axis. The support unit 90 is connected to each of the plurality of first films 72, and maintains the spacing along the Z-axis between the plurality of first films 72.

The support unit 90 may be provided in any position in the first stacked body 70A to the extent that it can support the plurality of first films 72. The support unit 90 may be provided in plural positions.

Next, as shown in FIG. 7 (step S103 of FIG. 4), a second stacked body 70B is formed. To form the second stacked body 70B, a first hole 91 penetrating through the first stacked body 70A along the Z-axis is formed. After that, the second films 73 are removed via the first hole 91. By removing the second film 73, the second stacked body 70B in which a space SC is formed between the plurality of first films 72 is formed.

Wet etching or dry etching is used for the removal of the second film 73. For example, in the case where a silicon nitride film or a silicon oxide film is used as the second film 73, an etchant is sent through the first hole 91 to remove the second film 73 with the etchant.

In the case where a silicon oxycarbide film is used as the second film 73, the second film 73 is removed through the first hole 91 by dry etching. For example, the second film 73 is removed through the first hole 91 by ashing using oxygen plasma.

In any etching, etching liquid or etching gas whereby the etching rate of the second film 73 is higher than the etching rate of the first film 72 is used. The etching proceeds from a portion of the second film 73 exposed at the inner wall of the first hole 91 to the inside. After the second film 73 is removed, the remaining plurality of first films 72 are kept in a state of being supported by the support unit 90.

Next, as shown in FIG. 8 (step S104 of FIG. 4), the plurality of through holes 30 are formed. The through hole 30 is formed to penetrate through the plurality of first films 72 of the second stacked body 70B along the Z-axis. For example, the silicon oxide film 26 is deposited on the second stacked body 70B, and a boron-doped polysilicon film 75 is deposited thereon. Next, the through holes 30 extending along the Z-axis are formed by photolithography and etching so as to penetrate through the boron-doped polysilicon film 75, the silicon oxide film 26, and the second stacked body 70B.

The through hole 30 is formed by, for example, RIE (reactive ion etching). The RIE is performed from the upper side to the lower side of the second stacked body 70B when forming the through hole 30 in the second stacked body 70B. Since a space is provided between the plurality of first films 72 of the second stacked body 70B, the surface 21a (upper surface) of each first film 72 on the opposite side to the substrate 11 is more etched than the surface 21b (lower surface) on the substrate 11 side when forming the through hole 30.

When the through hole 30 is formed, a first edge portion 210 is provided at the surface 21a of each first film 72, and a second edge portion 211 is provided at the surface 21b of each first film 72.

At this time, as shown in FIG. 3, for example, a portion with a first curvature R1 is formed in the first edge portion 210, and a portion with a second curvature R2 is formed in the second edge portion 211. Since the surface 21a of each first film 72 is more etched than the surface 21b, the first curvature R1 is smaller than the second curvature R2. (the curvature radius of the first edge portion 210 is larger than the curvature radius of the second edge portion 211.)

Alternatively, the first edge portion 210 has roundness, and the second edge portion 211 does not have roundness.

In the embodiment, when forming the through hole 30 by etching, the plurality of first films 72 of the second stacked body 70B are to be etched. Therefore, in the formation of the through hole 30, since only the first films 72 are etched, etching time is short and further etching conditions are simplified as compared to the case of etching the first stacked body 70A formed of the first films 72 and the second films 73.

Next, as shown in FIG. 9 (step S105 of FIG. 4), the memory film 33 is buried in the through hole 30, and the semiconductor layer 39 is buried in the remaining space of the through hole 30. Thus, the nonvolatile semiconductor memory device 110 is manufactured with high productivity.

The nonvolatile semiconductor memory device 110 manufactured by the embodiment mentioned above includes, for example, the plurality of electrode films 21 stacked along a first axis (the Z-axis) orthogonal to the major surface 11a of the substrate 11, the semiconductor layer 39 opposed to the side surfaces 21s of the plurality of electrode films 21, and the memory film 33 provided between the plurality of electrode films 21 and the semiconductor layer 39.

The first edge portion 210 of the surface 21a of the electrode film 21 on the opposite side to the substrate 11 includes a portion having a curvature (the first curvature R1) smaller than the curvature (the second curvature R2) of the second edge portion 211 of the surface 21b of the electrode film 21 on the substrate 11 side.

Next, a specific example of the method for manufacturing a nonvolatile semiconductor memory device according to the embodiment is described.

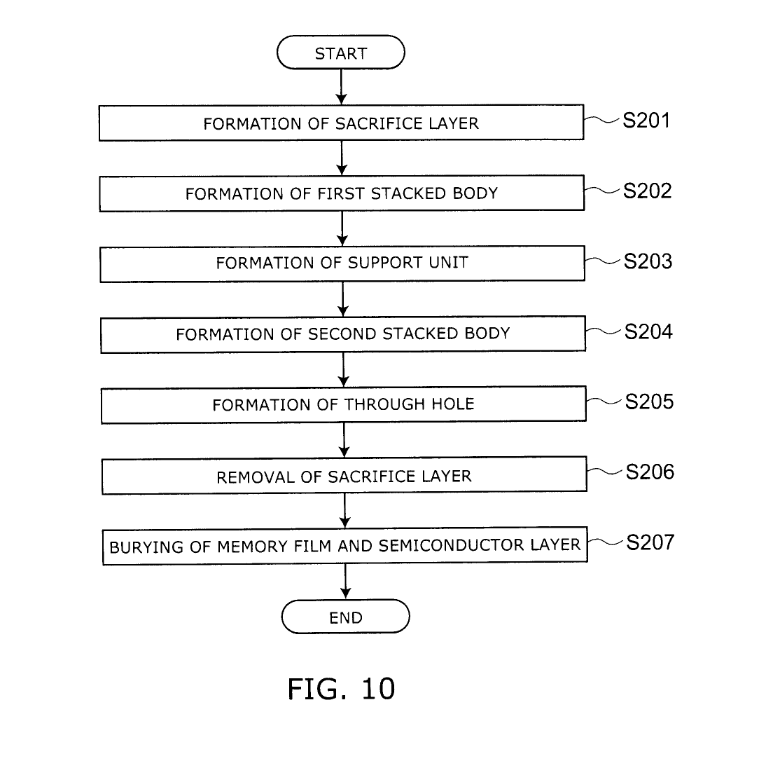

FIG. 10 is a flow chart illustrating a specific example of the manufacturing method according to the embodiment.

The method for manufacturing a nonvolatile semiconductor memory device according to the specific example includes formation of a sacrifice layer (step S201), formation of the first stacked body (step S202), e formation of the support unit (step S203), formation of the second stacked body (step S204), formation of the through hole (step S205), removal of the sacrifice layer (step S206), and burying of the memory film and the semiconductor layer (step S207).

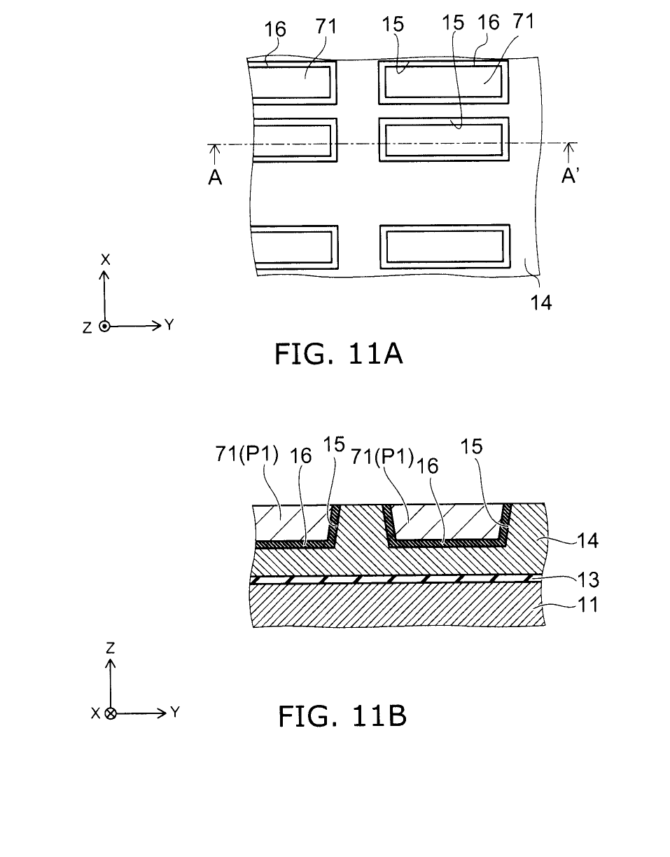

FIG. 11A to FIG. 19B are schematic views illustrating the method for manufacturing a nonvolatile semiconductor memory device according to the specific example.

Of FIG. 11A to FIG. 19B, the drawings of the numbers including “A” are schematic plan views, and the drawings of the numbers including “B” are schematic cross-sectional views taken along line A-A′ of the respective drawings of the numbers including “A”.

FIG. 11A to FIG. 19B show the memory array region Rm of the nonvolatile semiconductor memory device 110. First, as shown in FIG. 2, the substrate 11 made of, for example, silicon is prepared. Then, an STI (shallow trench isolation) 12 is selectively formed in an upper portion of the substrate 11. Next, the transistor 61 is formed in the peripheral circuit region Rc. In the memory array region Rm, the silicon oxide film 13 is formed on the upper surface of the substrate 11.

Next, as shown in FIGS. 11A and 11B, in the memory array region Rm, a film made of polysilicon doped with phosphorus is deposited and patterned to form the back gate electrode 14. Next, the recess 15 in a shape of, for example, a rectangular parallelepiped with the longitudinal direction along the Y-axis is formed at the upper surface of the back gate electrode 14 by the photolithography method. The recess 15 is formed in a plurality. The plurality of recesses 15 are provided in a matrix configuration along the X-axis and the Y-axis.

Next, the silicon oxide film 16 is formed on the inner surface of the recess 15. Next, silicon not doped with an impurity (non-doped silicon) is deposited on the entire surface, and overall etching is performed. Thereby, the non-doped silicon is removed from the upper surface of the back gate electrode 14 and left in the recess 15. The upper surface of the back gate electrode 14 is exposed between the recesses 15. The non-doped silicon unit 71 is buried in the recess 15. The portion where the non-doped silicon unit 71 is buried is a sacrifice layer P1 that forms the connection member 40 in a later process.

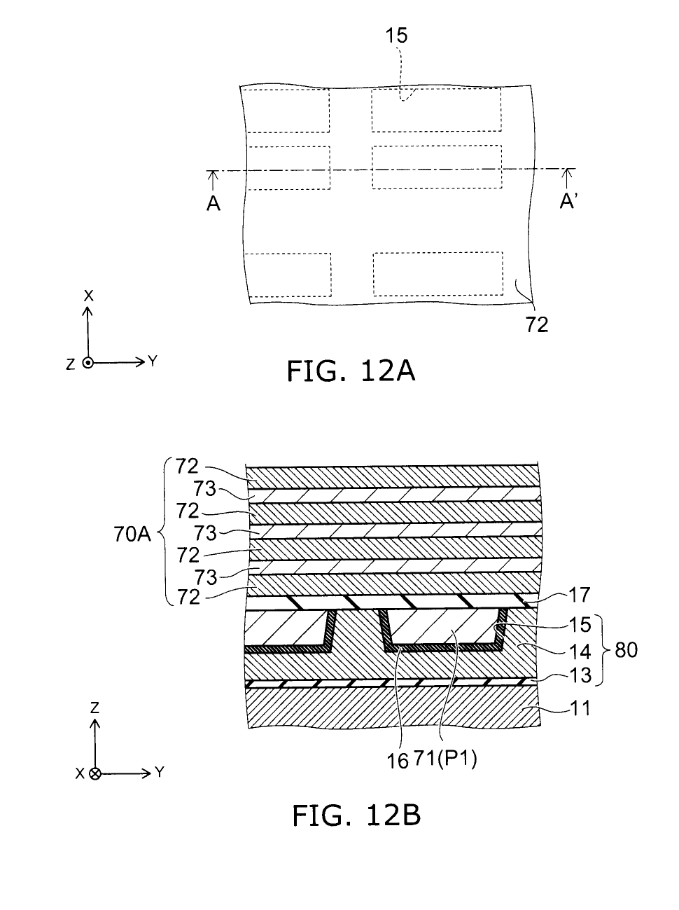

Next, as shown in FIGS. 12A and 12B, the silicon oxide film 17 is deposited on the entire upper surfaces of the back gate electrode 14, the silicon oxide film 16, and the non-doped silicon unit 71. Thereby, the structure body 80 is formed. The film thickness of the silicon oxide film 17 is set to a film thickness that ensures a breakdown voltage between the back gate electrode 14 and the lowermost electrode film 21 out of the electrode films 21 formed on the silicon oxide film 17 in a later process.

Next, the first films 72 and the second films 73 are alternately stacked on the structure body 80. A boron-doped polysilicon layer doped with boron is used as the first film 72. At least one of, for example, a silicon oxide film, a silicon nitride film, and a silicon oxycarbide film is used as the second film 73. The plurality of first films 72 and the plurality of second films 73 are alternately stacked one by one to form the first stacked body 70A.

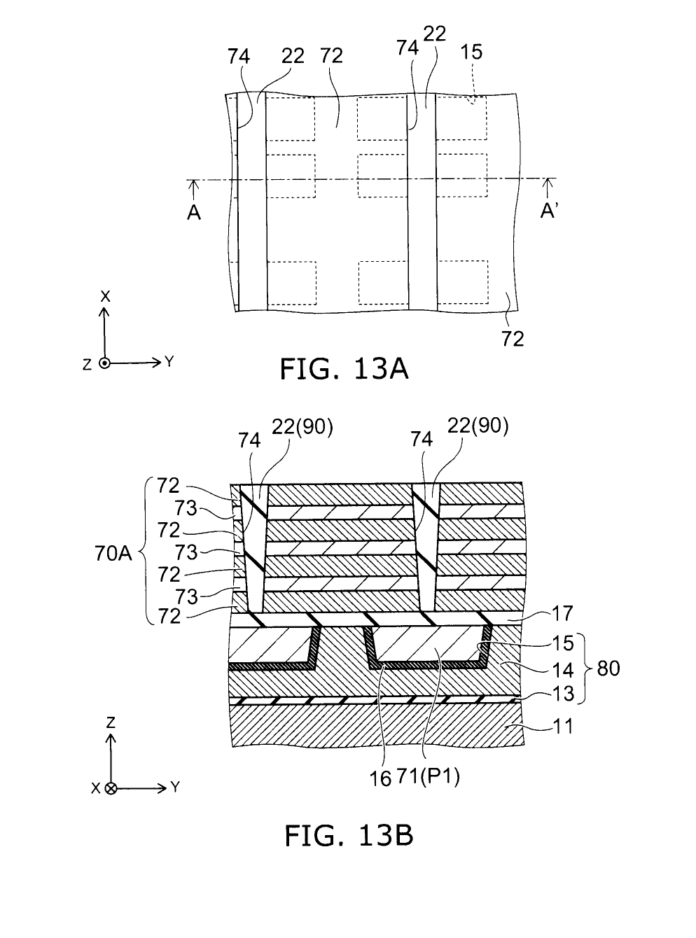

Next, as shown in FIGS. 13A and 13B, photolithography and etching are performed to form a slit 74 that is an example of a second hole in the first stacked body 70A. The opening of the slit 74 is in a shape of a long hole along the X-axis. The slit 74 is formed so as to penetrate through the first stacked body 70A along the Z-axis and pass through a region immediately above a central portion along the Y-axis of the recess 15. The slit 74 is individually provided immediately above each recess 15. The first film 72 is divided in the X direction by the slit 74.

Next, an insulating material such as silicon oxide is deposited on the entire surface. At this time, the insulating material is buried also in the slit 74. After that, overall etching is performed to remove the insulating material from the upper surface of the first stacked body 70A. The insulating material remains in the slit 74. Thereby, the insulating plate member 22 in a plate shape extending in the X-axis and Z-axis directions is formed in the slit 74. In the specific example, the insulating plate member 22 is used as the support unit 90. The first film 72 that forms the uppermost electrode film 21 is exposed at the upper surface of the first stacked body 70A.

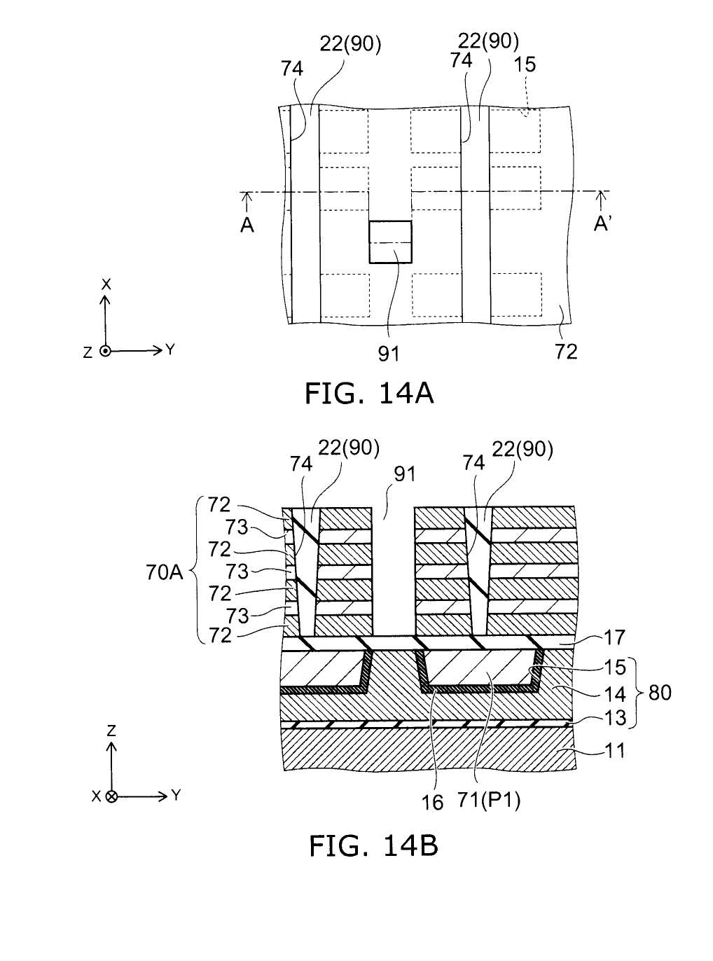

Next, as shown FIGS. 14A and 14B, the first hole 91 is formed in the first stacked body 70A. The first hole 91 penetrates through the first stacked body 70A along the Z-axis. In the specific example, as viewed in a direction along the Z-axis, the first hole 91 is formed in a position where the recess 15 is not provided. The opening of the first hole 91 is in a shape of a rectangle, circle, or the like. The first hole 91 may be provided in plural positions.

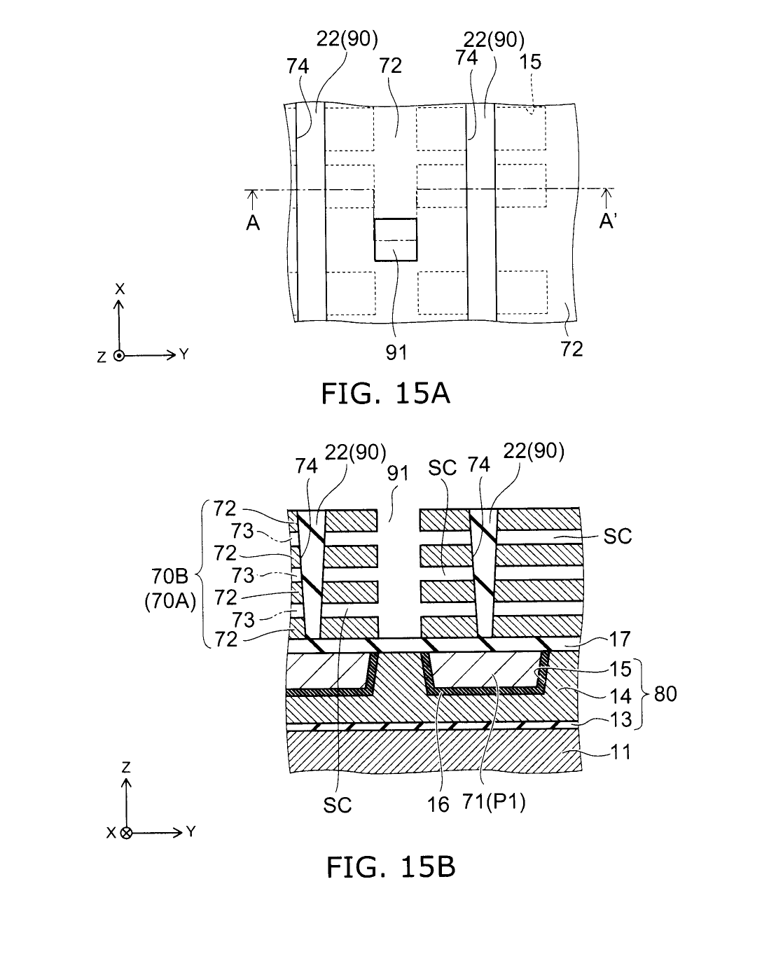

Next, as shown in FIGS. 15A and 15B, the second film 73 is removed via the first hole 91. By removing the second film 73 from the first stacked body 70A, the second stacked body 70B is formed. In the case where a silicon nitride film or a silicon oxide film is used as the second film 73, etchant is sent through the first hole 91 to remove the second film 73 with the etchant. In the case where a silicon oxycarbide film is used as the second film 73, the second film 73 is removed through the first hole 91 by dry etching. For example, the second film 73 is removed through the first hole 91 by ashing using oxygen plasma.

In the second stacked body 70B, the space SC is provided between the plurality of first films 72 along the Z-axis. Even when the space SC is present between the plurality of first films 72, each first film 72 is kept in a state of being supported by the support unit 90.

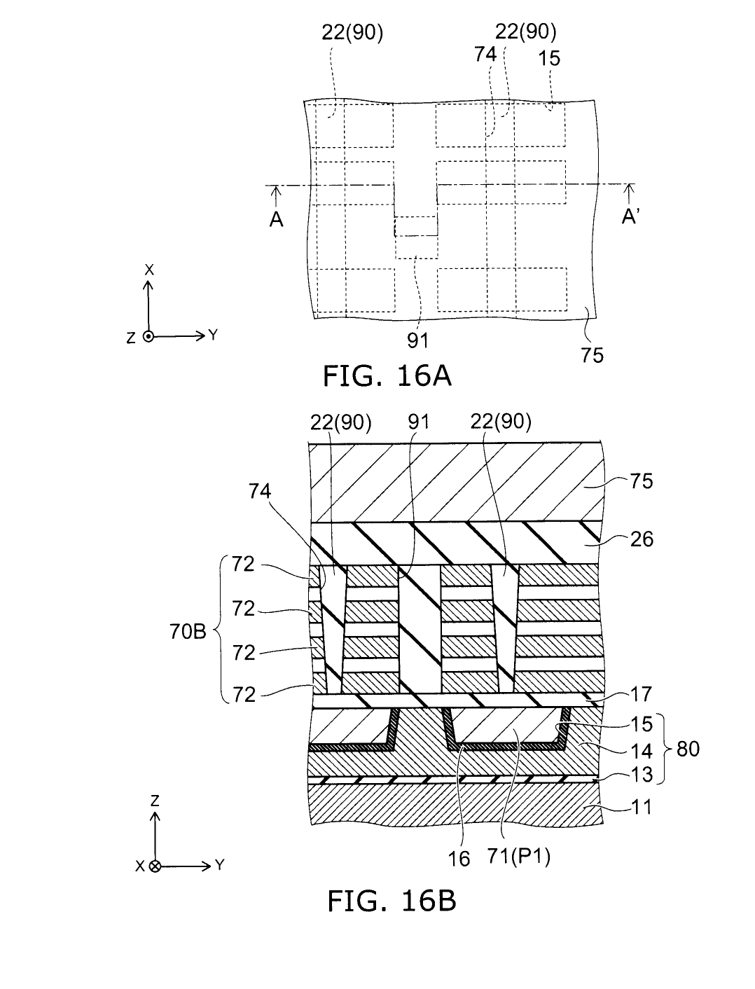

Next, as shown in FIGS. 16A and 16B, the silicon oxide film 26 is deposited on the second stacked body 70B, and the boron-doped polysilicon film 75 is deposited thereon. At this time, the film thickness of the silicon oxide film 26 is set to a film thickness that can sufficiently ensure a breakdown voltage between the first film 72 that forms the uppermost electrode film 21 and the boron-doped polysilicon film 75.

The silicon oxide film 26 is buried also in the first hole 91. The first hole 91 may be entirely filled with the silicon oxide film 26, or may be partially filled with the silicon oxide film 26 with a space provided.

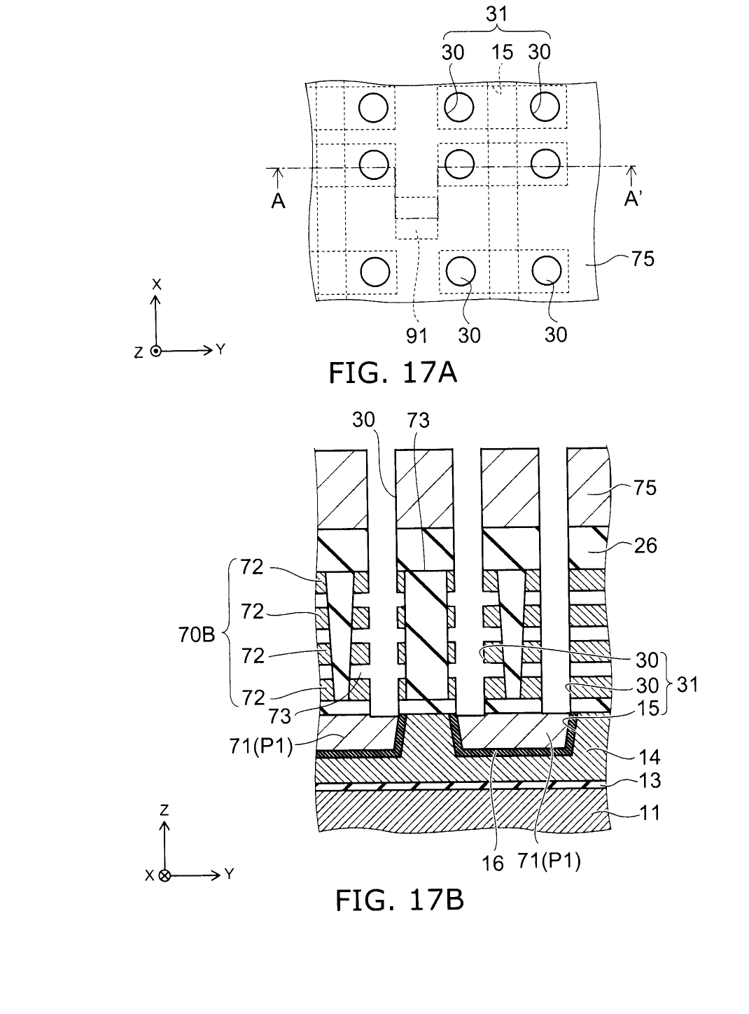

Next, as shown in FIGS. 17A and 17B, the plurality of through holes 30 extending in the Z direction are formed by photolithography and etching so as to penetrate through the boron-doped polysilicon film 75, the silicon oxide film 26, and the second stacked body 70B.

The through hole 30 is formed by, for example, RIE. At this time, only the plurality of first films 72 of the second stacked body 70B are to be etched. Therefore, etching time is short in this etching processing as compared to the case of etching the first stacked body 70A formed of the first film 72 and the second film 73. Furthermore, with regard to etching conditions, it is sufficient to set only the conditions for etching the first film 72. Thereby, etching conditions are simplified.

The through hole 30 is formed in, for example, a circular shape as viewed in a direction along the Z-axis. The through holes 30 are arranged in a matrix configuration along the X-axis and the Y-axis, and a pair of through holes 30 adjacent along the Y-axis are caused to reach both ends along the Y-axis of the recess 15.

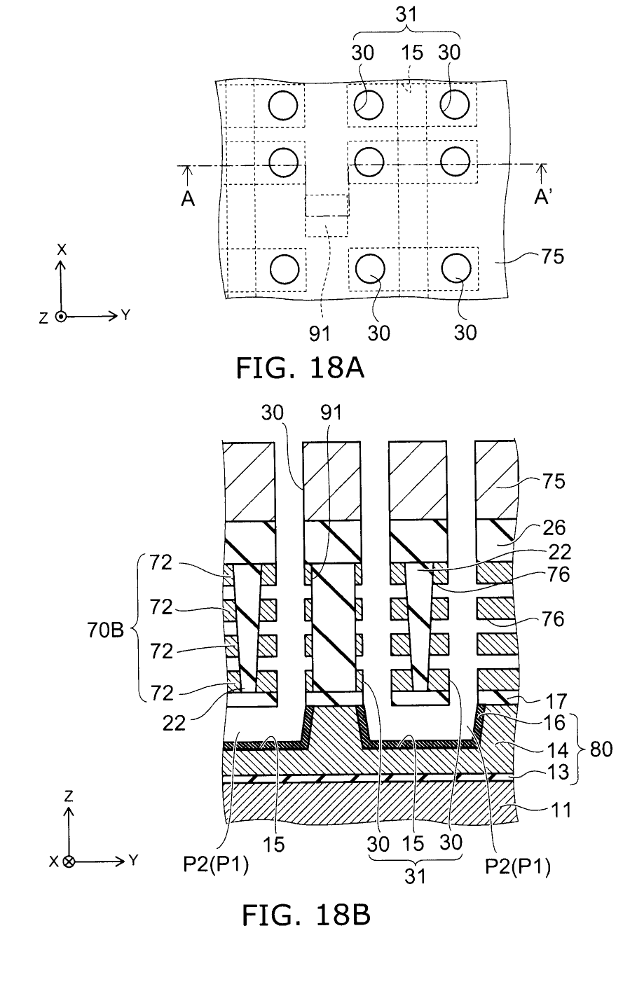

Next, as shown in FIGS. 18A and 18B, wet etching is performed via the through hole 30. An alkaline etchant, for example, is used for the wet etching. Thereby, the non-doped silicon unit 71 (see FIG. 17B), that is, the sacrifice layer P1 in the recess 15 is removed. By removing the non-doped silicon unit 71, the portion of the recess 15 where the sacrifice layer P1 was provided becomes a space P2. The U-shaped hole 31 in which the space P2 in one recess 15 and a pair of through holes 30 are connected together is formed.

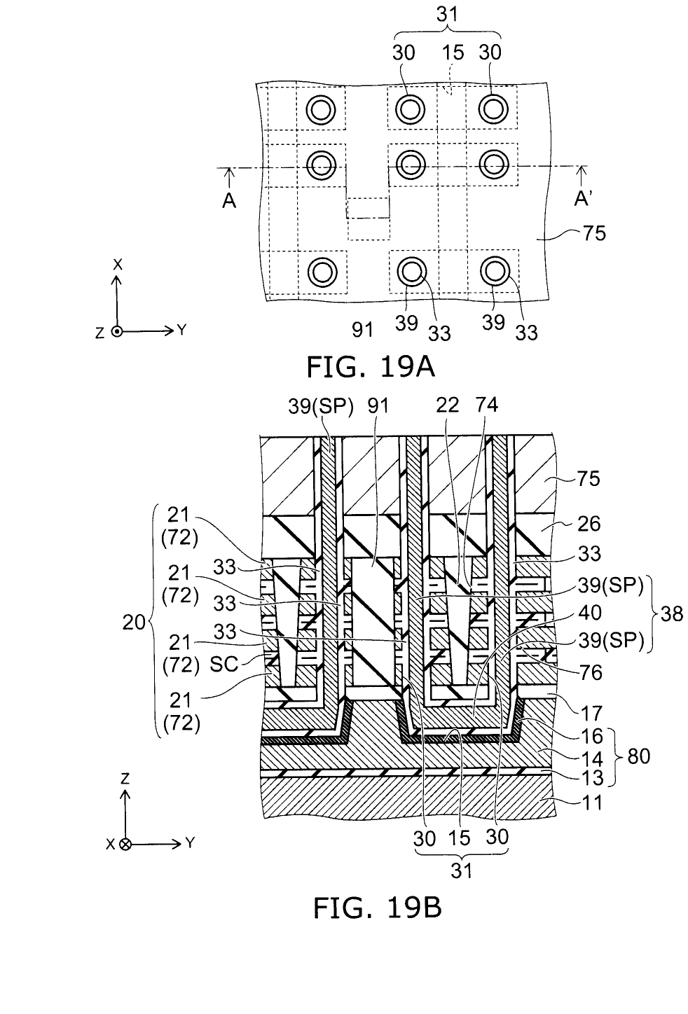

Next, as shown in FIGS. 19A and 19B, for example, the

ALD (atomic layer deposition) method is used to deposit silicon oxide. The silicon oxide enters the U-shaped hole 31 to deposit the block insulating film 35 on the inner surface of the U-shaped hole 31. Furthermore, the silicon oxide enters also the space SC via the through hole 30.

Next, silicon nitride is deposited. Thereby, the charge storage film 36 is formed on the block insulating film 35. At this time, since the interior of the space SC is filled with the block insulating film 35, the charge storage film 36 does not enter the space SC but is formed only in the U-shaped hole 31.

Next, a silicon oxide film is deposited. Thereby, the tunnel insulating film 37 is formed on the charge storage film 36. Also the tunnel insulating film 37 does not enter the space SC but is formed only in the U-shaped hole 31. The memory film 33 is formed from the block insulating film 35, the charge storage film 36, and the tunnel insulating film 37.

Next, polysilicon doped with an impurity such as phosphorus is buried in the U-shaped hole 31. Thereby, the U-shaped pillar 38 is formed in the U-shaped hole 31. Of the U-shaped pillar 38, the portion located in the through hole 30 forms the semiconductor pillar SP extending along the Z-axis, and the portion located in the recess 15 forms the connection member 40 extending along the Y-axis. The first film 72 penetrated through by the semiconductor pillar SP functions as the electrode film 21.

Next, etching is performed on the entire surface, and the polysilicon, the tunnel insulating film 37, the charge storage film 36, and the block insulating film 35 deposited on the boron-doped polysilicon film 75 are removed to expose the boron-doped polysilicon film 75.

After that, as shown in FIG. 2, the interlayer insulating film 42 is formed, and the source line 47 and the interconnections 49 and 50 are formed on the interlayer insulating film 42. Furthermore, the interlayer insulating film 42 is deposited to form the plug 48. Then, the bit line 51 and the interconnection 52 are formed on the interlayer insulating film 42, the silicon nitride film 54 is formed thereon, and the interlayer insulating film 55 is formed thereon. Thus, the nonvolatile semiconductor memory device 110 is completed.

In such a manufacturing method, since etching time in forming the through hole 30 is shortened and etching conditions are further simplified, the nonvolatile semiconductor memory device 110 is manufactured with high productivity.

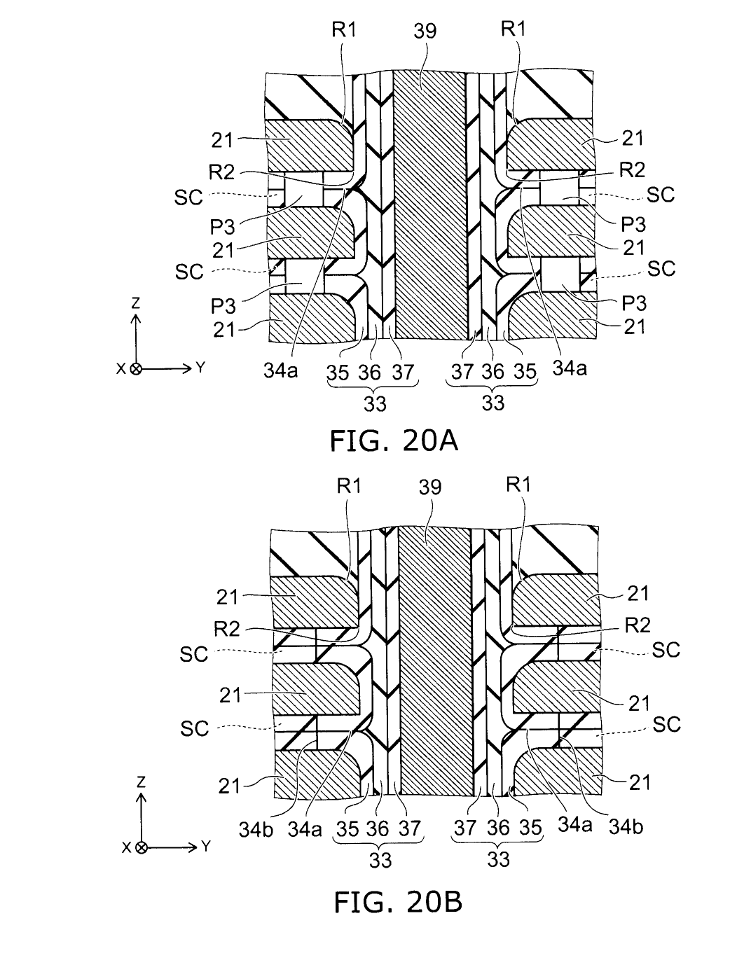

FIGS. 20A and 20B are schematic cross-sectional views illustrating the formation of the memory film.

FIG. 20A shows a first example of the memory film, and FIG. 20B shows a second example of the memory film.

In the memory film 33 shown in FIG. 20A, the block insulating film 35 is embedded partway in the space SC. The block insulating film 35 is formed on both the upper and lower surfaces of the electrode film 21. Therefore, between two electrode films 21 adjacent along the Z-axis, the block insulating film 35 formed on the lower surface of the upper electrode film 21 and the block insulating film 35 formed on the upper surface of the lower electrode film 21 are in contact to form a seam 34a at the contact surface. Since the block insulating film 35 is embedded partway in the space SC, a space P3 is provided between two electrode films 21 adjacent along the Z-axis.

In the memory film 33 shown in FIG. 20B, the block insulating film 35 is formed so as to entirely fill the space SC. The seam 34a of the block insulating film 35 is formed between two electrode films 21 adjacent along the Z-axis. The block insulating films 35 are formed from both one end and the other end, respectively, along the Y-axis of the electrode film 21 toward the central portion. A seam 34b is formed at the contact surface between the block insulating film 35 on one side and the block insulating film 35 on the other side.

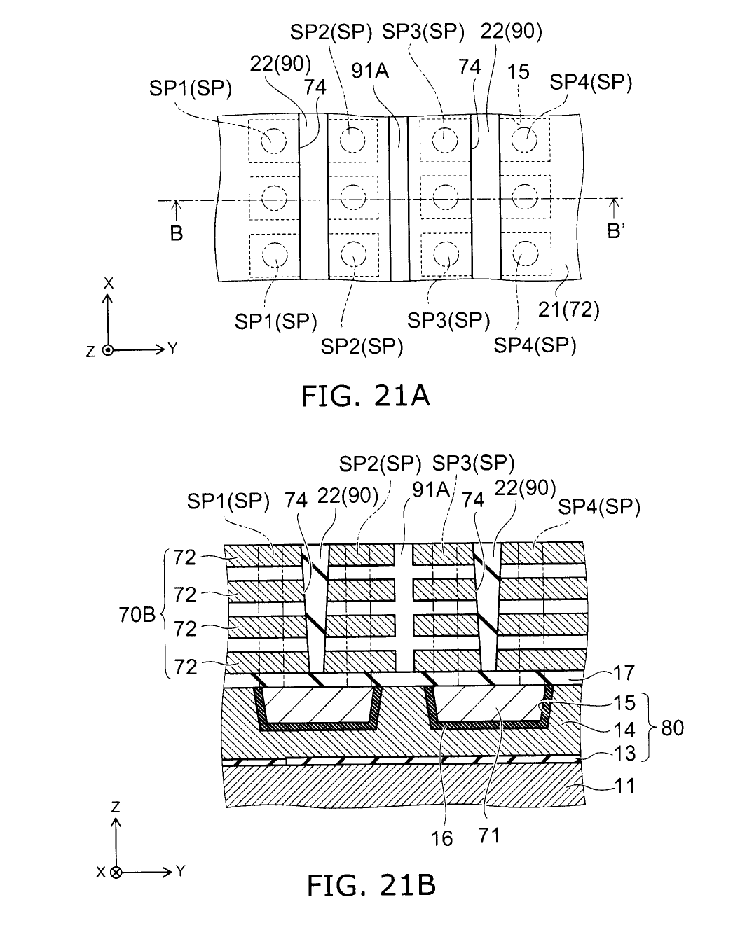

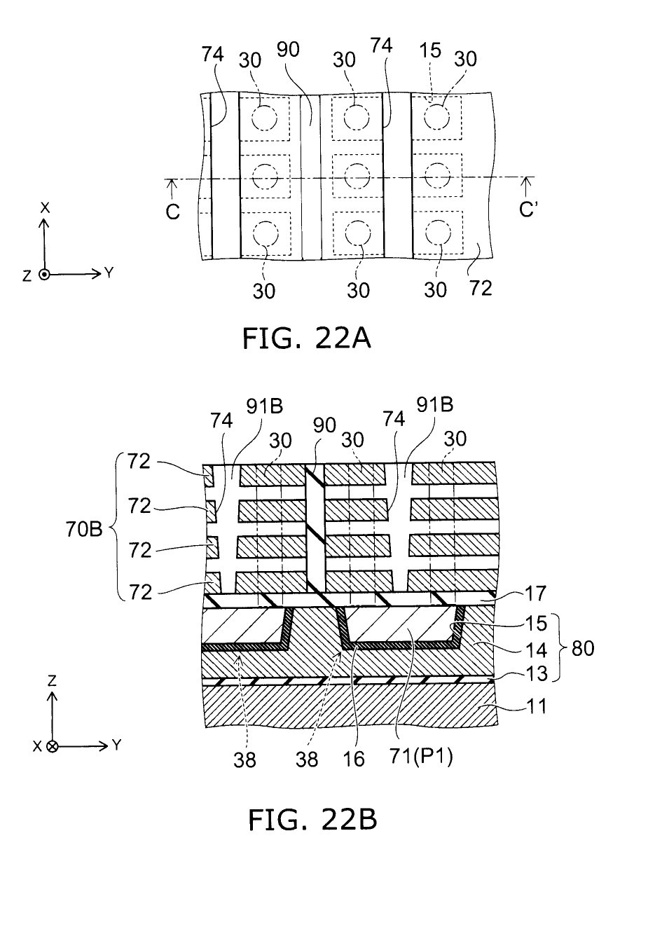

FIG. 21A to FIG. 22B are schematic views showing other examples of the first hole.

FIG. 21A is a schematic plan view, and FIG. 21B is a schematic cross-sectional view taken along line B-B′ of FIG. 21A.

FIG. 22A is a schematic plan view, and FIG. 22B is a schematic cross-sectional view taken along line C-C′ of FIG. 22A.

A first hole 91A shown in FIGS. 21A and 21B is formed in a slit shape along the X-axis. The first hole 91A is provided between two recesses 15 adjacent along the Y-axis. That is, the first hole 91A is formed in a position between the two semiconductor pillars SP2 and SP3 adjacent along the Y-axis in two U-shaped memory strings. The first film 72 is divided along the X-axis by the first hole 91A.

The first hole 91A is used in removing the second film 73 by etching, and also used as a slit for dividing the first film 72 along the X-axis. By dividing the first film 72 along the X-axis, a nonvolatile semiconductor memory device including independent electrode films 21 between semiconductor pillars SP adjacent along the Y-axis is manufactured.

A first hole 91B shown in FIG. 22 is provided on the sacrifice layer P1 in the recess 15. The first hole 91B is formed in a slit shape along the X-axis. The first hole 91B is used in removing the second film 73 by etching, and also used as a slit for dividing the first film 72 along the X-axis on the recess 15. The support unit 90 is provided between two recesses 15 and in other portions. The through hole 30 provided in the second stacked body 70B is individually provided on both sides of the first hole 91B as viewed in a direction along the Z-axis. That is, the first hole 91B divides the first film 72 along the X-axis inside the U-shaped pillar 38.

As shown in FIG. 21A to FIG. 22B, by using the first holes 91A and 91B also as a slit for dividing the first film 72 along the X-axis, the memory array region Rm saves space as compared to the case of providing the first hole 91 separately.

The positions where the first hole 91 and the support unit 90 are provided are not limited to the examples described above. That is, they may be formed in positions other than the examples described above to the extent that the second film 73 can be removed via the first hole 91 and the first film 72 can be supported by the support unit 90.

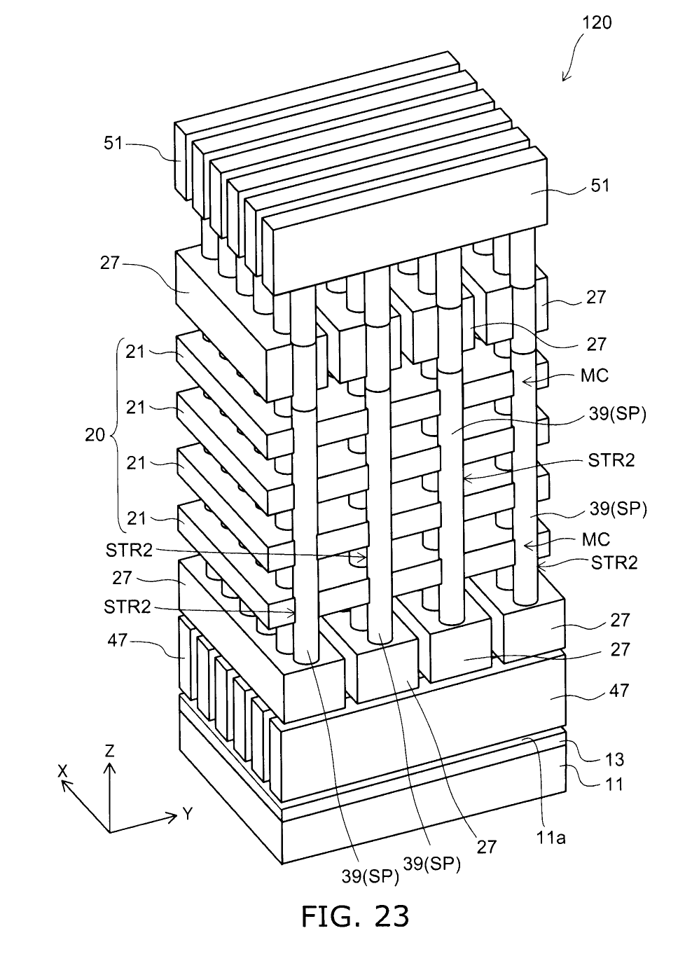

FIG. 23 is a schematic perspective view illustrating the configuration of another nonvolatile semiconductor memory device.

The manufacturing method according to the embodiment is applied to the method for manufacturing a nonvolatile semiconductor memory device 120 shown in FIG. 23.

As shown in FIG. 23, in the nonvolatile semiconductor memory device 120, the connection member 40 is not provided, and each of the semiconductor pillars SP is independent. That is, a memory string STR2 in a rectilinear shape is provided in the nonvolatile semiconductor memory device 120.

In the nonvolatile semiconductor memory device 120, a control electrode 27 is individually provided on the upper side and the lower side of the stacked body 20. The control electrode 27 is provided for each set of a plurality of semiconductor pillars SP aligned along the X-axis. A plurality of source lines 47 are provided between the control electrode 27 on the lower side and the substrate 11, and extend along the Y-axis. A plurality of bit lines 51 are provided above the control electrode 27 on the upper side, and extend along the Y-axis.

The manufacturing method according to the embodiment, that is, the manufacturing method including the formation of the support unit 90, the formation of the second stacked body 70B, and the formation of the through hole 30 can be applied also to the nonvolatile semiconductor memory device 120 thus configured.

As described above, the embodiment provides a method for manufacturing a nonvolatile semiconductor memory device with high productivity.

Hereinabove, the embodiment and modification examples thereof are described, but the invention is not limited to these examples. For example, one skilled in the art may appropriately make additions, removals, and design changes of components to the embodiments or the modification examples thereof described above, and may appropriately combine features of the embodiments; such modifications also are included in the scope of the invention to the extent that the spirit of the invention is included.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a nonvolatile semiconductor memory device including a plurality of electrode films stacked along a first axis perpendicular to a major surface of a substrate, a plurality of semiconductor layers penetrating through the plurality of electrode films along the first axis, and a memory film provided between the plurality of electrode films and the semiconductor layer, comprising:
forming a first stacked body by alternately stacking a plurality of first films and a plurality of second films, the plurality of first films forming the plurality of electrode films;
forming a support unit lying along the first axis, and the unit supporting the plurality of first films;
forming a first hole penetrating through the first stacked body along the first axis and removing the second films via the first hole to form a second stacked body with a space formed between the plurality of first films;
forming a plurality of through holes penetrating through the plurality of first films of the second stacked body along the first axis; and
burying the memory film and the semiconductor layers in the plurality of through holes.

2. The method according to claim 1, wherein the forming the support unit includes forming a second hole penetrating through the first stacked body along the first axis and forming the support unit supporting the plurality of first films in the second hole.

3. The method according to claim 1, wherein the forming the second stacked body includes forming an opening of the first hole into a long hole shape along a second axis parallel to the major surface and perpendicular to the first axis.

4. The method according to claim 3, wherein the forming the second stacked body includes dividing the first film in a direction along the second axis by the first hole.

5. The method according to claim 3, wherein the forming the through hole includes forming the through hole individually on both sides of the first hole as viewed in a direction along the first axis.

6. The method according to claim 1, further comprising:
burying a sacrifice layer in the major surface of the substrate before the forming the first stacked body; and
removing the sacrifice layer,
the forming the plurality of through holes including causing two of the plurality of through holes to reach the sacrifice layer,
the removing the sacrifice layer including removing the sacrifice layer via the two through holes to form a space,
the burying the memory film and burying the semiconductor layer including burying the memory film and burying the semiconductor layer in the space via the two through holes.

7. The method according to claim 6, wherein the forming the second stacked body includes forming the first hole in a position between the two through holes.

8. The method according to claim 1, wherein the forming the second stacked body includes removing the second film by wet etching.

9. The method according to claim 1, wherein the forming the second stacked body includes removing the second film by dry etching.

10. A nonvolatile semiconductor memory device comprising:
a plurality of electrode films stacked along a first axis orthogonal to a major surface of a substrate;
a semiconductor layer facing side surfaces of the plurality of electrode films; and
a memory film provided between the plurality of electrode films and the semiconductor layer,
a first edge portion of a surface of one of the electrode film on an opposite side to the substrate including a portion having a curvature smaller than a curvature of a second edge portion of a surface of the electrode film on a side of the substrate.

11. The device according to claim 10, wherein a space is provided between the plurality of electrode films.

12. The device according to claim 10, wherein the semiconductor layer includes a semiconductor pillar provided in a columnar shape along the first axis.

13. The device according to claim 10, further comprising a connection portion including the semiconductor pillar in a plurality and connected to both ends on the side of the substrate of two of the semiconductor pillars adjacent along the major surface.

14. The device according to claim 10, wherein
the semiconductor layer penetrates through the second stacked body along the first axis and
the memory film surrounds the semiconductor layer along the first axis.

15. The device according to claim 10, wherein the memory film includes a stacked film in which an insulating layer containing an oxide, a second insulating layer containing a nitride, and a third insulating layer containing an oxide are sequentially stacked in a direction from the electrode film to the semiconductor layer.

16. The device according to claim 15, wherein the insulating layer is provided in the space.

17. The device according to claim 15, wherein a seam is provided in the insulating layer provided in the space.
